(19) United States
(12) Patent Application Publication
(10) Pub. No.: US 2013/0298973 A1
(43) Pub. Date: Nov. 14, 2013

(54) TUNNELING-JUNCTION SOLAR CELL WITH SHALLOW COUNTER DOPING LAYER IN THE SUBSTRATE

(71) Applicants: Zhigang Xie, San Jose, CA (US); Jiunn Benjamin Heng, San Jose, CA (US); Jianming Fu, Palo Alto, CA (US); Zheng Xu, Pleasanton, CA (US)

(72) Inventors: Zhigang Xie, San Jose, CA (US); Jiunn Benjamin Heng, San Jose, CA (US); Jianming Fu, Palo Alto, CA (US); Zheng Xu, Pleasanton, CA (US)

(73) Assignee: SILEVO, INC., Fremont, CA (US)

(21) Appl. No.: 13/601,521

(22) Filed: Aug. 31, 2012

Related U.S. Application Data
(60) Provisional application No. 61/646,706, filed on May 14, 2012.

(51) Int. Cl. H01L 31/0352; H01L 31/18

(52) U.S. Cl. 136/255; 438/87; 257/E31.032

(57) ABSTRACT

One embodiment of the present invention provides a tunneling junction solar cell. The solar cell includes a base layer, an emitter layer situated adjacent to the shallow counter doping layer, a surface field layer situated adjacent to a side of the base layer opposite to the shallow counter doping layer, a front-side electrode, and a back-side electrode. The base layer includes a shallow counter doping layer having a conduction doping type that is opposite to a remainder of the base layer. The emitter layer has a bandgap that is wider than that of the base layer.

### RELATED APPLICATION

This application claims the benefit of U.S. Provisional Application No. 61/646,706, Attorney Docket Number SSP12-1002PSP, entitled “Shallow Counter Doping Layer in C—Si Substrate to Improve Performance on Tunneling Heterojunction Solar Cells,” by inventors Zhigang Xie, Jiunn Benjamin Heng, Jianming Fu, and Zheng Xu, filed 14 May 2012.

The subject matter of this application is related to the subject matter of U.S. patent application Ser. No. 12/945,792 (Attorney Docket Number SSP10-1002US), entitled “Solar Cells with Oxide Tunneling Junctions,” by inventors Jiunn Benjamin Heng, Chentao Yu, Zheng Xu, and Jianming Fu, filed 12 Nov. 2010, the disclosure of which is incorporated by reference in its entirety herein.

### BACKGROUND

1. Field

This disclosure is generally related to solar cells. More specifically, this disclosure is related to a tunneling junction solar cell that has a shallow counter doping layer in the substrate.

2. Related Art

The negative environmental impact caused by the use of fossil fuels and their rising cost have resulted in a dire need for cleaner, cheaper alternative energy sources. Among different forms of alternative energy sources, solar power has been favored for its cleanness and wide availability.

A solar cell converts light into electricity using the photoelectric effect. There are many solar cell structures and a typical solar cell contains a p-n junction that includes a p-type doped layer and an n-type doped layer. In addition, there are other types of solar cells that are not based on p-n junctions. For example, a solar cell can be based on a metal-insulator-semiconductor (MIS) structure that includes an ultra-thin dielectric or insulating interfacial tunneling layer situated between a metal or a highly conductive layer and a doped semiconductor layer.

Among various types of solar cells, silicon heterojunction (SHJ) solar cells have drawn attention for their high efficiency. For example, U.S. Pat. No. 5,705,828 discloses a double-sided heterojunction solar cell, which achieves high efficiency using excellent surface passivation. The key improvement of a double-sided heterojunction solar cell is a higher open circuit voltage (V_{oc}), such as greater than 715 mV (compared with the 600 mV V_{oc} of the conventional crystalline Si-based solar cells).

Other approaches to obtain high-efficiency solar cells by improving passivation at the emitter surface have been proposed. U.S. Pat. No. 5,705,828 and U.S. Pat. No. 7,030,413 describe a surface-passivation method that uses an intrinsic semiconductor layer, such as a layer of intrinsic a-Si. The intrinsic a-Si layer can provide excellent passivation for the crystalline Si emitter by lowering the number of surface dangling bonds and reducing the minority carrier concentration. The latter effect is the result of the surface field (formed by the valence band offset), which pushes minority carriers away from the interface and the emitter.

In addition, U.S. Pat. No. 5,213,628 and U.S. Pat. No. 7,737,357 describe tunneling-based heterojunction devices that can provide excellent open-circuit voltage (V_{oc}) from the combination of the field effect and surface passivation. However, these tunneling-based heterojunction devices often suffer from a lower short-circuit (J_{sc}) current because the tunneling barrier inevitably blocks the flow of majority carriers.

### SUMMARY

One embodiment of the present invention provides a tunneling-junction solar cell. The solar cell includes a base layer, an emitter layer situated adjacent to the shallow counter doping layer, a surface field layer situated adjacent to a side of the base layer opposite to the shallow counter doping layer, a front-side electrode, and a back-side electrode. The base layer includes a shallow counter doping layer having a conduction doping type that is opposite to a remainder of the base layer. The emitter layer has a bandgap that is wider than that of the base layer.

In a variation on the embodiment, the base layer includes at least one of: a mono-crystalline silicon wafer, an epitaxially grown crystalline-Si (c-Si) thin film, and an epitaxially grown crystalline-Si (c-Si) thin film with graded doping.

In a variation on the embodiment, the shallow counter doping layer has a graded doping concentration, and a peak value of the graded doping ranges between 1×10¹⁸/cm³ and 5×10²°/cm³.

In a variation on the embodiment, the shallow counter doping layer has a thickness that is less than 300 nm.

In a variation on the embodiment, the shallow counter doping layer is formed using at least one of: doping silicate glass by thermal drive-in of dopants, doping a-Si by thermal drive-in of dopants, doping multi-crystalline Si by thermal drive-in of dopants, ion implantation, and exptaxially growing a layer of doped c-Si.

In a variation on the embodiment, the solar cell further includes at least one of: a first quantum-tunneling-barrier (QTB) layer between the base layer and the emitter layer, and a second QTB layer between the base layer and the surface field layer.

In a further variation, the first and/or the second QTB layer includes at least one of: silicon oxide (SiOₓ), hydrogenated SiOₓ, silicon nitride (SiNₓ), hydrogenated SiNₓ, aluminum oxide (AlOₓ), silicon oxynitride (SiON), hydrogenated SiON, and one or more wide bandgap semiconductor materials.

In a further variation, the first and/or the second QTB layers have a thickness between 1 and 50 angstroms.

In a further variation, wherein the first and/or the second QTB layers are formed using at least one of the following techniques: thermal oxidation, atomic layer deposition, wet or steam oxidation, low-pressure radical oxidation, and plasma-enhanced chemical-vapor deposition (PECVD).

In a variation on the embodiment, the emitter layer and/or the surface field layer include at least one of: amorphous-Si (a-Si), polycrystalline Si, and one or more wide bandgap semiconductor materials.

In a further variation, the emitter layer and/or the surface field layer comprise a graded-doped amorphous-Si (a-Si) layer with a doping concentration ranging between 1×10¹⁵/cm³ and 5×10²⁰/cm³.

In a variation on the embodiment, the emitter layer is situated at a front side of the base layer facing the incident sunlight.

In a variation on the embodiment, the emitter layer is situated at a back side of the base layer facing away from the incident sunlight.

### BRIEF DESCRIPTION OF THE FIGURES

FIG. 1A presents a diagram illustrating an exemplary tunneling-junction solar cell with a shallow counter doping layer in the substrate, in accordance with an embodiment of the present invention.

FIG. 1B presents a diagram illustrating the energy diagram at the emitter-base interface for a solar cell with and without shallow counter doping in the substrate, in accordance with an embodiment of the present invention.

FIG. 1C presents a diagram illustrating the energy diagram at the emitter-base interface for a solar cell with and without shallow counter doping in the substrate, in accordance with an embodiment of the present invention.

FIG. 1D presents a diagram illustrating the comparison of the tunneling current and the drift current for a solar cell with and without shallow counter doping in the substrate, in accordance with an embodiment of the present invention.

FIG. 1E presents a diagram illustrating the comparison of the tunneling current and the drift current for a solar cell with and without shallow counter doping in the substrate, in accordance with an embodiment of the present invention.

FIG. 1F presents a diagram illustrating the carrier density of a solar cell without shallow counter doping in the substrate.

FIG. 1G presents a diagram illustrating the carrier density of a solar cell with shallow counter doping in the substrate, in accordance with an embodiment of the present invention.

FIG. 2 presents a diagram illustrating the process of fabricating a tunneling junction solar cell with shallow counter doping layer in the substrate, in accordance with an embodiment of the present invention.

FIG. 3 presents a diagram illustrating an exemplary tunneling-junction solar cell with shallow counter doping layer in the substrate, in accordance with an embodiment of the present invention.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a crystalline-Si (c-Si)-based solar cell having a shallow counter doping layer situated in the c-Si substrate. The solar cell further includes a quantum-tunneling barrier (QTB) layer. The counter doping can be achieved by doping the surface of the c-Si with a dopant that has an opposite conduction type than that of the c-Si substrate. The doping depth is as shallow as possible to achieve a maximum boosting effect of the short-circuit current (J_{sc}).

Heterolunction Solar Cell with Shallow Counter Doping in the Substrate

Heterojunction-based solar cells have demonstrated superior performance when compared with other types of solar cells. To further enhance performance, some heterojunction solar cells reap the advantage of band bending at the emitter-base interface, which creates a “field-effect” passivation that effectively passivates the emitter surface. However, the heterojunction needs to have very low internal and interface recombination rates. To achieve such a goal, a thin layer of low conductivity semiconductor material (such as a semiconductor material with a wider bandgap, a lower mobility, and lower doping), or dielectric film is often formed at the heterojunction interface to function as a QTB layer.

In conventional heterojunction solar cells, excess carriers are forced to flow toward and collected by the emitter, usually on the opposite side of the heterojunction. Unless the internal excess carrier concentration is higher than a certain level and is capped by Auger recombination, most of the recombination is Shockley-Read-Hall (SRH) recombination. Hence, it is desirable to have a low minority carrier concentration inside the solar cell in order to keep the recombination rate low. Tunneling-based heterojunction solar cells provide a lower minority carrier concentration by blocking the flow of minority carriers, thus resulting in a lowered recombination rate. However, despite being able to provide a higher V_{oc}, conventional tunneling-based heterojunction solar cells do suffer from a lower J_{sc} because the flow of majority carriers is blocked as well.

Moreover, the tunneling current is impacted by majority carrier concentration at the interface. Conventional tunneling-based heterojunction solar cells tend to have very low tunneling current due to the fact that the number of defect states in the substrate is often low as the substrate is often lightly doped to a certain conduction type (p or n). Although one can control the majority carrier concentration during the depositions of the passivation layer and the emitter layer, such an approach may not be desirable under certain circumstances, because it may lead to high absorption loss or low film quality in the high doping region, or lead to thermal damage during the thermal activation of the dopants. Other problems facing the conventional tunneling-based heterojunction solar cells include the existence of the carrier depletion region at the emitter-base interface.

To mitigate these effects that negatively impact J_{sc} in tunneling-based solar cells, embodiments of the present invention provide a solution that significantly enhances J_{sc} by shallowly counter doping the solar cell substrate. More specifically, during fabrication, the emitter-facing side of the substrate is doped with a dopant having an opposite conduction type as that of the substrate. The penetration depth of the dopant is carefully controlled to obtain the best J_{sc} boost effect. In one embodiment, the distance from the surface to where the doping concentration decays to 1/e its peak value (at the substrate surface) is less than 100 nm, and the junction depth (the distance to where the doping concentration decays to the background level) is less than 300 nm. In a further embodiment, the maximum concentration of this counter doping (or the doping concentration at the substrate surface) is between 1×10¹⁸/cm³ and 5×10²⁰/cm³.

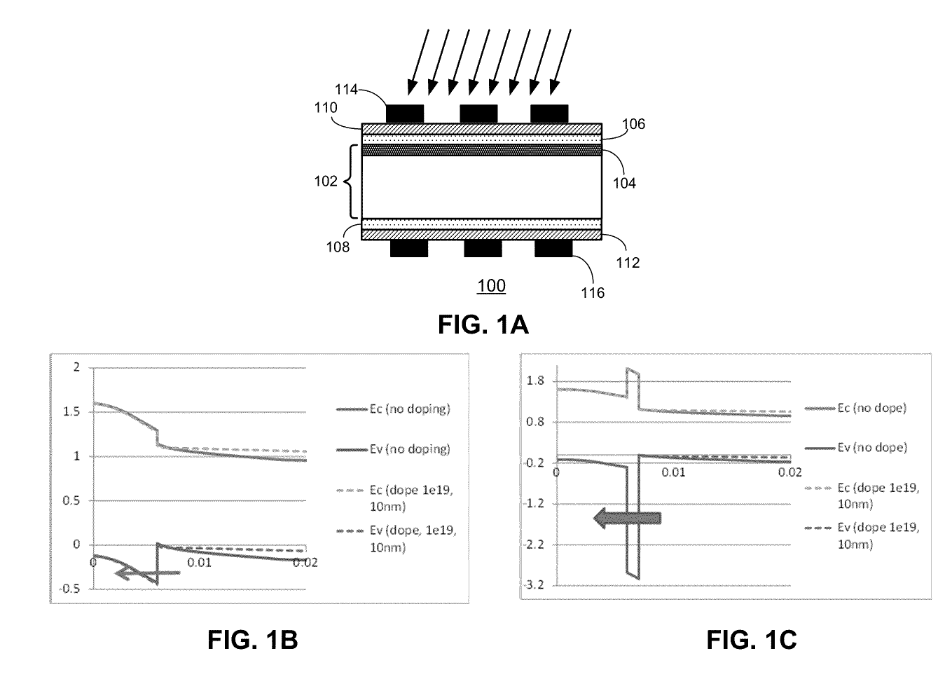

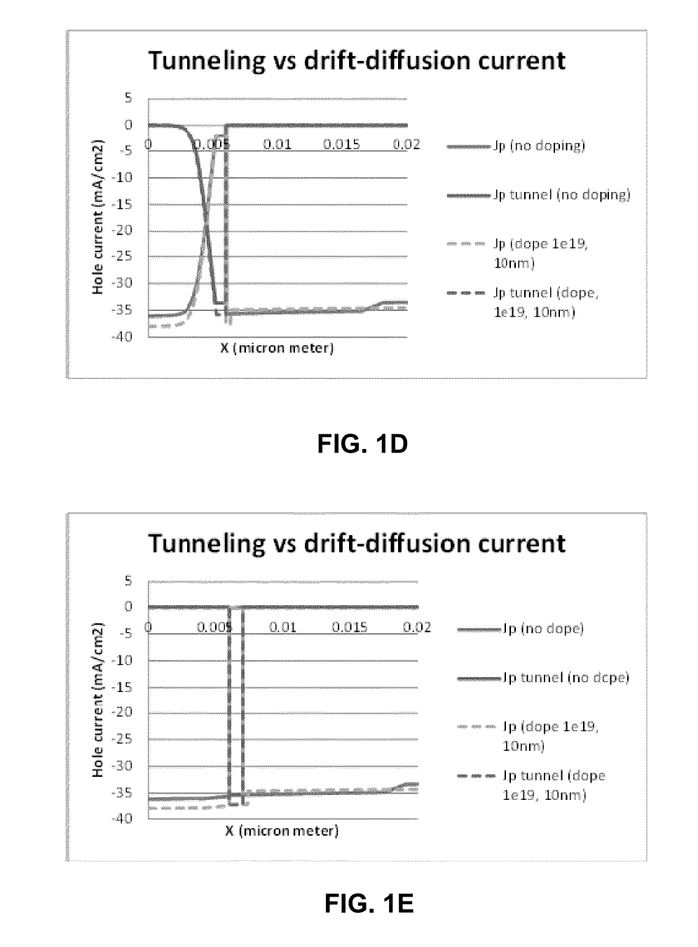

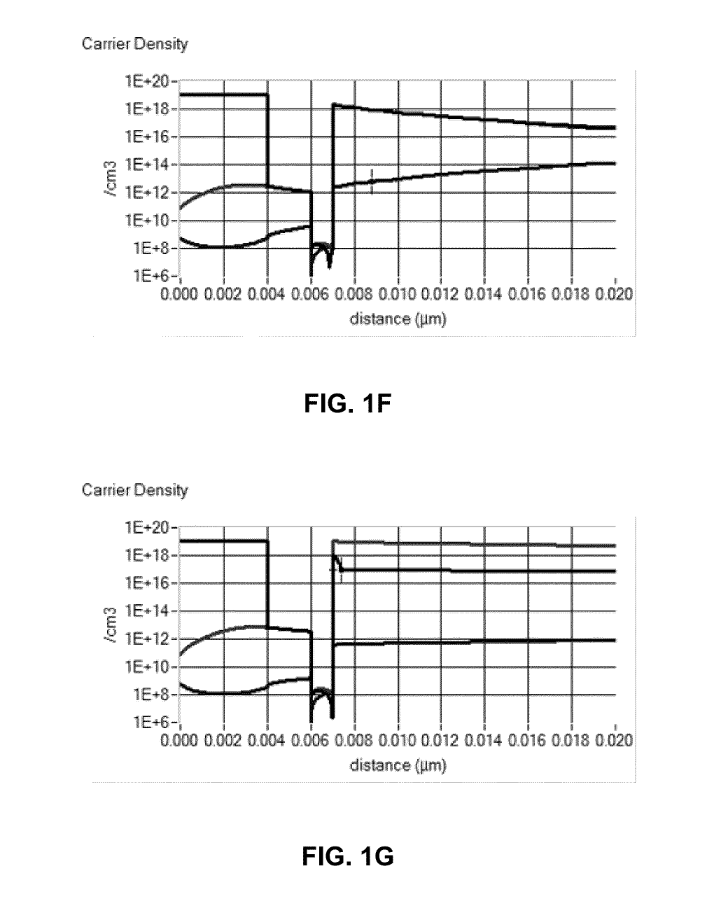

FIG. 1A presents a diagram illustrating an exemplary tunneling-junction solar cell with a shallow counter doping layer in the substrate, in accordance with an embodiment of the present invention. Solar cell 100 includes a substrate 102, which includes a shallow counter doping layer 104; optional ultra-thin QTB layers 106 and 108 covering the front and back surfaces of substrate 102, respectively; an emitter layer 110; a back surface field (BSF) layer 112; a front electrode 114; and a back electrode 116. Arrows indicate sunlight

Note that, to ensure high efficiency, substrate 102 often includes a lightly doped crystalline silicon (c-Si) substrate that is in one conduction type, either n-type or p-type. The majority of the body of substrate 102 has a doping concentration that is less than 1×10¹⁷/cm³. QTB layers 106 and 108 can include dielectric or wide bandgap materials. Emitter 110 also includes heavily doped wide bandgap materials having a conduction type opposite to that of substrate 102. Note that both QTB layer 106 and emitter 110 have a wider bandgap compared with c-Si substrate 102. Consequently, in the energy band diagram, the bottom of the conduction band of the emitter/QTB layer is much higher than that of the substrate. Similarly, the top of the valence band of the emitter/QTB layer is much lower than that of the substrate. The wider bandgap combined with lower mobility makes tunneling the dominant conduction mechanism for solar cell 100, while providing excellent passivation.

As discussed above, due to the wide bandgap property of the emitter/QTB layer, majority carriers diffuse into the bulk c-Si substrate. This can get worse for emitters with opposite doping of the substrate because of depletion. For example, for a solar cell with an n⁻ doped c-Si substrate and a p⁺ doped wide bandgap (such as a-Si) emitter, a fairly wide space charge region (depletion region) exists at the p⁺-n⁻ heterojunction interface. Note that, unlike homogenous junctions, there is a tunneling barrier for majority carriers at the heterojunction interface even without the QTB layer. This tunneling barrier at a typical heterojunction (p⁺-n⁻ or n⁺-p⁻) interface can contribute up to 3% loss of J_{sc}. The artificially introduced QTB layer also makes the tunneling of majority carriers more difficult and can contribute up to 2% loss of J_{sc}.

In another aspect, the heterojunction passivates the emitter-base interface by increasing majority carrier concentration and suppressing minority carrier concentration. This passivation relies on band bending, which is limited by the property of the emitter/QTB film and there is little room for improvement.

In embodiments of the present invention, by introducing a shallow counter doping region on the emitter-facing side of the substrate, one can considerably increase the tunneling current as the counter doping provides more defect states, removing the block to majority carriers while continuing to suppress minority carriers at the interface. FIG. 1B presents a diagram illustrating the energy diagram at the emitter-base interface for a solar cell with and without shallow counter doping in the substrate, in accordance with an embodiment of the present invention. In FIG. 1B, the tunneling barrier is formed by the lightly doped or intrinsic wide bandgap semiconductor film. The energy band diagram is calculated at one sun and short circuit condition. As one can see, there is a triangle barrier at the interface. Without the shallow doping (the solid lines), the electric field is almost continuous across the interface and there is not enough surface charge. With shallow counter doping (dashed lines), holes (in the case of the substrate being n-type doped) will fill the interface defect states and help tunneling from right to the left (as suggested by the arrow). Note that, because the boundary condition has to be satisfied, electrical field on the right side (substrate side) is much lower.

FIG. 1C presents a diagram illustrating the energy diagram at the emitter-base interface for a solar cell with and without shallow counter doping in the substrate, in accordance with an embodiment of the present invention. In FIG. 1C, the tunneling barrier is formed by the lightly doped or intrinsic wide bandgap semiconductor film and an insulating dielectric film. The energy band diagram is calculated at one sun and short circuit condition. Similarly to FIG. 1B, the tunneling current (holes moving from right to left) receives a boost from the shallow counter doping.

FIG. 1D presents a diagram illustrating the comparison of the tunneling current and the drift current for a solar cell with and without shallow counter doping in the substrate, in accordance with an embodiment of the present invention. In FIG. 1D, the tunneling barrier is formed by the lightly doped or intrinsic wide bandgap semiconductor film. As one can see, the current is mostly based on tunneling, but a small amount of drift-diffusion current also exists. FIG. 1D also demonstrates that the shallow counter doping close to the barrier boosts the hole tunneling current, as shown by the dashed lines.

FIG. 1E presents a diagram illustrating the comparison of the tunneling current and the drift current for a solar cell with and without shallow counter doping in the substrate, in accordance with an embodiment of the present invention. In FIG. 1E, the tunneling barrier is formed by the lightly doped or intrinsic wide bandgap semiconductor film and an insulating dielectric film, and all currents are tunneling-based. Like FIG. 1D, FIG. 1E also demonstrates that the short circuit current is boosted by the shallow counter doping. Note that FIGS. 1D-1E only plot hole currents, through either drift diffusion or tunneling. There is a small percentage of electron current contributing to the total current on the substrate side of the barrier.

FIG. 1F presents a diagram illustrating the carrier density of a solar cell without shallow counter doping in the substrate. FIG. 1G presents a diagram illustrating the carrier density of a solar cell with shallow counter doping in the substrate, in accordance with an embodiment of the present invention. In both FIGS. 1F and 1G, the carrier density is calculated at V=0.6 V and one sun condition, which is the condition close to a maximum power output. In both figures, the bottom line is the minority carrier concentration in log scale, and the middle line is the majority carrier concentration. As one can see, in FIG. 1G, the minority carrier concentration at the interface is 2 to 3 times lower than that of FIG. 1F, showing shallow counter doping significantly lowering recombination at the interface. FIGS. 1B-1G are all plotted for an n-type substrate.

### Fabrication Method

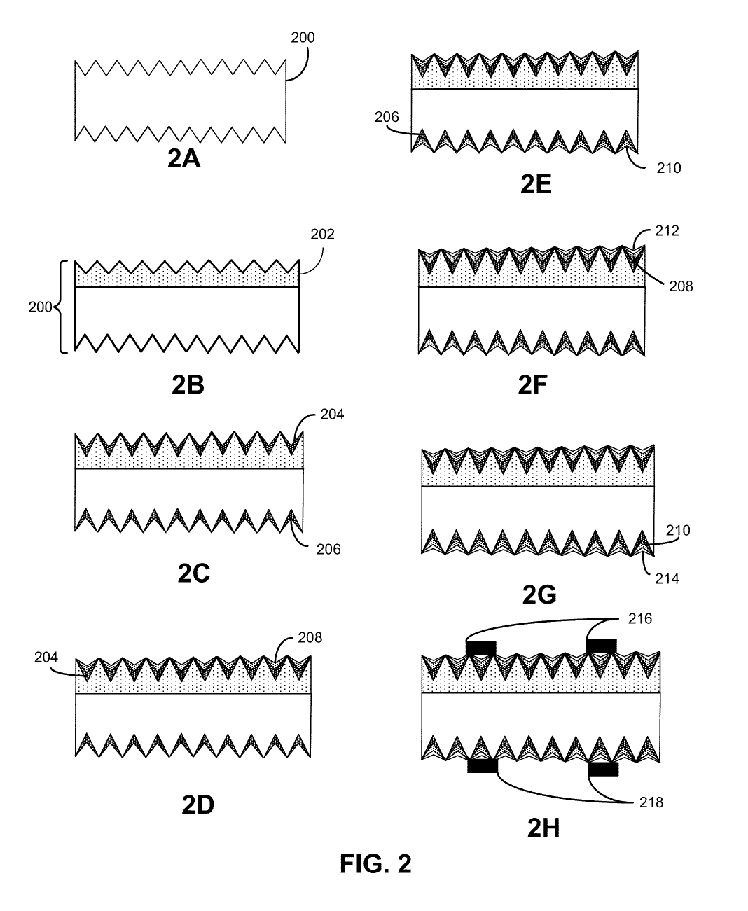

Either n- or p-type doped high-quality solar-grade silicon (SG-Si) wafers can be used to build the solar cell. In one embodiment, an n-type doped SG-Si wafer is selected. FIG. 2 presents a diagram illustrating the process of fabricating a tunneling junction solar cell with a shallow counter doping layer in the substrate, in accordance with an embodiment of the present invention.

In operation 2A, an SG-Si substrate 200 (such as an SG-Si wafer) is prepared. The thickness of SG-Si substrate 200 can range between 20 and 300 μm. The resistivity of SG-Si substrate 200 is typically in, but is not limited to, the range between 1 ohm-cm and 10 ohm-cm. In one embodiment, SG-Si substrate 200 has a resistivity between 1 ohm-cm and 2 ohm-cm. The preparation operation includes typical saw damage etching that removes approximately 10 μm of silicon and surface texturing. The surface texture can have various patterns, including but not limited to: hexagonal-pyramid, inverted pyramid, cylinder, cone, ring, and other irregular shapes. In one embodiment, the surface texturing operation results in a random pyramid textured surface. Afterwards, SG-Si substrate 200 goes through extensive surface cleaning.

In operation 2B, a shallow counter doping layer 202 is formed on the surface of SG-Si substrate 200 by doping the surface of SG-Si substrate 200 using a dopant having an opposite conduction type than that of SG-Si substrate 200 or by epitaxially growing a thin layer of c-Si having an opposite doping type. For example, if SG-Si substrate 200 is n-type doped, shallow counter doping layer 202 is then formed by heavily doping (between 1×10¹⁸/cm³ and 1×10²°/cm³) the surface of SG-Si substrate 200 using a p-type dopant, and vice versa. vise versa. Various techniques can be used to form shallow counter doping layer 202, including but not limited to: doping of silicate glass with thermal drive-in of dopants, doping of amorphous/multi-crystalline Si with thermal drive-in of dopants, ion implantation, and epitaxial growth of a c-Si layer with an opposite doping type. Note that, if shallow counter doping layer 202 is formed by epitaxial growth, the surface texturing may need to be performed after the growth. To achieve optimal J_{sc} boosting, the thickness (or the penetration depth) of shallow counter doping layer 202 is kept as small as possible. In reality, the doping concentration is always highest at the surface and decreases as the depth increases. In one embodiment, the distance from the substrate surface to where the doping concentration decays to 1/e its peak value is less than 100 nm, and the junction depth (the distance to where the doping concentration decays to the background level of the substrate) is less than 300 nm. In a further embodiment, the peak value of this counter doping (or the doping concentration at the substrate surface) is between 1×10¹⁸/cm³ and 5×10²°/cm³.

In operation 2C, a thin layer of high-quality (with defect state density less than 1×10¹¹/cm²) dielectric material is deposited on the front and back surfaces of SG-Si substrate 200 to form front and back passivation/tunneling layers 204 and 206, respectively. In one embodiment, only the front surface (the surface facing the emitter) of SG-Si substrate 200 is deposited with a thin layer of dielectric material. Various types of dielectric material can be used to form the passivation/tunneling layers, including, but not limited to: silicon oxide (SiOₓ), hydrogenated SiOₓ, silicon nitride (SiNₓ), hydrogenated SiN_{X}, aluminum oxide (AlOₓ), aluminum nitride (AlNₓ), silicon oxynitride (SiON), and hydrogenated SiON. Other than dielectric materials, passivation/tunneling layers 204 and 206 can also include a lightly doped or intrinsic widegap semiconductor material, or a combination of both. In addition, various deposition techniques can be used to deposit the passivation/tunneling layers, including, but not limited to: thermal oxidation, atomic layer deposition, wet or steam oxidation, low-pressure radical oxidation, plasma-enhanced chemical-vapor deposition (PECVD), etc. The thickness of passivation/tunneling layers 204 and 206 can be between 1 and 50 angstroms. In one embodiment, passivation/tunneling layers 204 and 206 have a thickness between 1 and 15 angstroms. Note that the well-controlled thickness of the passivation/tunneling layers ensures good passivation and tunneling effects.

In operation 2D, a layer of hydrogenated, graded-doping a-Si having a doping type opposite to that of SG-Si substrate 200 is deposited on the surface of front passivation/tunneling layer 204 to form emitter layer 208. As a result, emitter layer 208 is situated on the front side of the solar cell facing the incident sunlight. Note that, if SG-Si substrate 200 is n-type doped, then emitter layer 208 is p-type doped, and vice versa. In one embodiment, emitter layer 208 is p-type doped using boron as dopant. The thickness of emitter layer 208 is between 1 and 20 nm, and the doping concentration of emitter layer 208 ranges between 1×10¹⁵/cm³ and 5×10²⁰/cm³. In one embodiment, the region within emitter layer 208 that is adjacent to front passivation/tunneling layer 204 has a higher doping concentration, and the region that is away from front passivation/tunneling layer 204 has a lower doping concentration. In addition to a-Si, it is also possible to use other material, including but not limited to: one or more wide-bandgap semiconductor materials and polycrystalline Si, to form emitter layer 208.

In operation 2E, a layer of hydrogenated, graded-doping a-Si having a doping type the same as that of SG-Si substrate 200 is deposited on the surface of back passivation/tunneling layer 206 to form back surface field (BSF) layer 210. Note that, if SG-Si substrate 200 is n-type doped, then BSF layer 210 is also n-type doped, and vice versa. In one embodiment, BSF layer 210 is n-type doped using phosphorous as dopant. In one embodiment, the thickness of BSF layer 210 is between 1 and 30 nm. In one embodiment, the doping concentration of BSF layer 210 varies from 1×10¹⁵/cm³ to 5×10²⁰/cm³. In addition to a-Si, it is also possible to use other material, including but not limited to: wide-bandgap semiconductor materials and polycrystalline Si, to form BSF layer 210.

In operation 2F, a layer of TCO material is deposited on the surface of emitter layer 208 to form a front-side conductive anti-reflection layer 212, which ensures a good ohmic contact. Examples of TCO include, but are not limited to: indium-tin-oxide (ITO), indium oxide (InO), indium-zinc-oxide (IZO), tungsten-doped indium-oxide (IWO), tin-oxide (SnOₓ), aluminum doped zinc-oxide (ZnO:Al or AZO), Zn—In—O (ZIO), gallium doped zinc-oxide (ZnO:Ga), and other large bandgap transparent conducting oxide materials.

In operation 2G, back-side TCO layer 214 is formed on the surface of BSF layer 210. Back-side TCO layer 214 forms a good anti-reflection coating to allow maximum transmission of sunlight into the solar cell.

In operation 2F, front-side electrode 216 and back-side electrode 218 are formed on the surfaces of TCO layers 212 and 214, respectively. In one embodiment, front-side electrode 216 and back-side electrode 218 include Ag finger grids, which can be formed using various techniques, including, but not limited to: screen printing of Ag paste, inkjet or aerosol printing of Ag ink, and evaporation. In a further embodiment, front-side electrode 216 and/or back-side electrode 218 can include a Cu grid formed using various techniques, including, but not limited to: electroless plating, electro plating, sputtering, and evaporation.

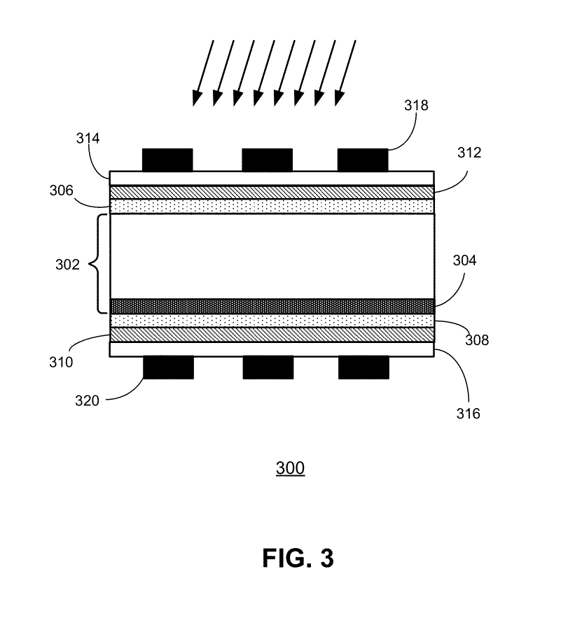

Note that the fabrication process illustrated in FIG. 2 is merely exemplary, and other variations are also possible. For example, in addition to using a c-Si wafer, SG-Si substrate 200 can also include an epitaxially grown c-Si film with a uniform or graded doping concentration. The doping concentration of the epitaxially grown c-Si film can be between 1×10¹⁴/cm³ and 1×10¹⁸/cm, and the thickness of the c-Si film can be between 20 μm and 100 μm. In addition, instead of having the emitter layer at the front-side (the side facing incident light) of the solar cell, it is possible to form the emitter layer on the back-side (the side facing away from incident light) of the solar cell. Note that in such a case the shallow counter doping layer is also formed on the back-side of the substrate to face the emitter. In addition, a front-surface field (FSF) layer is formed on the front-side of the substrate. FIG. 3 presents a diagram illustrating an exemplary tunneling junction solar cell with a shallow counter doping layer in the substrate, in accordance with an embodiment of the present invention. Solar cell 300 includes a substrate 302, which includes a shallow counter doping layer 304; optional ultra-thin QTB layers 306 and 308 covering the front and back surfaces of substrate 302, respectively; an emitter layer 310; a front surface field (FSF) layer 312; front and back TCO layers 314 and 316; a front electrode 318; and a back electrode 320. Arrows indicate sunlight.

Detailed descriptions of the various fabrication methods for fabricating a tunneling junction solar cell can be found in U.S. patent application Ser. No. 12/945,792 (Attorney Docket Number SSP10-1002US), entitled “Solar Cells with Oxide Tunneling Junctions,” by inventors Jiunn Benjamin Heng, Chentao Yu, Zheng Xu, and Jianming Fu, filed 12 Nov. 2010, the disclosure of which is incorporated by reference in its entirety herein.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A method for fabricating a tunneling junction solar cell, comprising:
obtaining a base layer for the solar cell, wherein the base layer includes a shallow counter doping layer having a conduction doping type that is opposite to a remainder of the base layer;
forming an emitter layer adjacent to the shallow counter doping layer, wherein the emitter layer has a bandgap that is wider than that of the base layer;
forming a surface field layer;
forming a front-side electrode; and
forming a back-side electrode.

2. The method of claim 1, wherein the base layer comprises at least one of:
a mono-crystalline silicon wafer; and
an epitaxially grown crystalline-Si (c-Si) thin film.

3. The method of claim 1, wherein the shallow counter doping layer has a graded doping concentration, and where a peak value of the graded doping ranges between 1×10¹⁸/cm³ and 5×10²⁰/cm³.

4. The method of claim 1, wherein the shallow counter doping layer has a thickness that is less than 300 nm.

5. The method of claim 1, wherein the shallow counter doping layer is formed using at least one of:
doping silicate glass by thermal drive-in of dopants;
doping a-Si by thermal drive-in of dopants;
doping multi-crystalline Si by thermal drive-in of dopants;
ion implantation; and
epitaxially growing a layer of doped c-Si.

6. The method of claim 1, further comprising at least one of:
forming a first quantum-tunneling-barrier (QTB) layer between the base layer and the emitter layer; and
forming a second QTB layer between the base layer and the surface field layer.

7. The method of claim 6, wherein the first and/or the second QTB layers comprise at least one of:
silicon oxide (SiOₓ);
hydrogenated SiOₓ;
silicon nitride (SiNₓ);
hydrogenated SiNₓ;
aluminum oxide (AlOₓ);
silicon oxynitride (SiON);
hydrogenated SiON; and
one or more wide bandgap semiconductor materials.

8. The method of claim 6, wherein the first and/or the second QTB layers have a thickness between 1 and 50 angstroms.

9. The method of claim 6, wherein the first and/or the second QTB layers are formed using at least one of the following techniques:
thermal oxidation;
atomic layer deposition;
wet or steam oxidation;
low-pressure radical oxidation; and
plasma-enhanced chemical-vapor deposition (PECVD).

10. The method of claim 1, wherein the emitter layer and/or the surface field layer comprise at least one of:
amorphous-Si (a-Si);
polycrystalline Si; and
one or more wide bandgap semiconductor materials.

11. The method of claim 10, wherein the emitter layer and/or the surface field layer comprise a graded-doped amorphous-Si (a-Si) layer with a doping concentration ranging between 1×10¹⁵/cm³ and 5×10²⁰/cm³.

12. The method of claim 1, wherein the emitter layer is situated at a front side of the base layer facing the incident sunlight.

13. The method of claim 1, wherein the emitter layer is situated at a back side of the base layer facing away from the incident sunlight.

14. A tunneling junction solar cell, comprising:
a base layer, wherein the base layer includes a shallow counter doping layer having a conduction doping type that is opposite to a remainder of the base layer;
an emitter layer situated adjacent to the shallow counter doping layer, wherein the emitter layer has a bandgap that is wider than that of the base layer;
a surface field layer situated adjacent to a side of the base layer opposite to the shallow counter doping layer;
a front-side electrode; and
a back-side electrode.

15. The solar cell of claim 14, wherein the base layer comprises at least one of:
a mono-crystalline silicon wafer;
an epitaxially grown crystalline-Si (c-Si) thin film; and
an epitaxially grown crystalline-Si (c-Si) thin film with graded doping.

16. The solar cell of claim 14, wherein the shallow counter doping layer has a graded doping concentration, and where a peak value of the graded doping ranges between 1×10¹⁸/cm³ and 5×10²⁰/cm³.

17. The solar cell of claim 14, wherein the shallow counter doping layer has a thickness that is less than 300 nm.

18. The solar cell of claim 14, wherein the shallow counter doping layer is formed using at least one of:
doping silicate glass by thermal drive-in of dopants;
doping a-Si by thermal drive-in of dopants;
doping multi-crystalline Si by thermal drive-in of dopants;
ion implantation; and
epitaxially growing a layer of doped c-Si.

19. The solar cell of claim 14, further comprising at least one of:
a first quantum-tunneling-barrier (QTB) layer between the base layer and the emitter layer; and
a second QTB layer between the base layer and the surface field layer.

20. The solar cell of claim 19, wherein the first and/or the second QTB layers comprise at least one of:
silicon oxide (SiOₓ);
hydrogenated SiOₓ;
silicon nitride (SiNₓ);
hydrogenated SiNₓ;
aluminum oxide (AlOₓ);
silicon oxynitride (SiON);
hydrogenated SiON; and
one or more wide bandgap semiconductor materials.

21. The solar cell of claim 19, wherein the first and/or the second QTB layers have a thickness between 1 and 50 angstroms.

22. The solar cell of claim 19, wherein the first and/or the second QTB layers are formed using at least one of the following techniques:
thermal oxidation;
atomic layer deposition;
wet or steam oxidation;
low-pressure radical oxidation; and
plasma-enhanced chemical-vapor deposition (PECVD).

23. The solar cell of claim 14, wherein the emitter layer and/or the surface field layer comprise at least one of:
amorphous-Si (a-Si);
polycrystalline Si; and
one or more wide bandgap semiconductor materials.

24. The solar cell of claim 23, wherein the emitter and/or the surface field layer comprise a graded-doped amorphous-Si (a-Si) layer with a doping concentration ranging between 1×10¹⁵/cm³ and 5×10²⁰/cm³.

25. The solar cell of claim 14, wherein the emitter layer is situated at a front side of the base layer facing the incident sunlight.

26. The solar cell of claim 14, wherein the emitter layer is situated at a back side of the base layer facing away from the incident sunlight.
